(19) United States
(12) Patent Application Publication
(10) Pub. No.: US 2021/0202338 A1
(43) Pub. Date: Jul. 1, 2021

(54) WAFER-LEVEL SIP MODULE STRUCTURE AND METHOD FOR PREPARING THE SAME

(71) Applicant: SJ Semiconductor (Jiangyin) Corporation, JiangYin City (CN)

(72) Inventors: Chengtar WU, JiangYin City (CN); Yenheng CHEN, JiangYin City (CN); Chengchung LIN, JiangYin City (CN)

(21) Appl. No.: 17/139,867

(22) Filed: Dec. 31, 2020

(30) Foreign Application Priority Data
Dec. 31, 2019 (CN) 2019114073585
Dec. 31, 2019 (CN) 2019224717993

(51) Int. Cl. H01L 23/31; H01L 21/48; H01L 21/56; H01L 23/498; H01L 23/00; H01L 23/552

(52) U.S. Cl. CPC H01L 23/3135; H01L 21/4853; H01L 21/4857; H01L 21/568; H01L 2224/16225; H01L 23/49822; H01L 23/49816; H01L 24/16; H01L 23/552; H01L 21/4864

(57) ABSTRACT

The present disclosure provides a wafer-level SiP module and a method for preparing the same. The method includes: forming conductive pillars on a substrate; attaching a chip to the substrate; forming a first plastic encapsulation layer on the substrate, the first plastic encapsulation layer encapsulating the conductive pillars and the chip; forming a rewiring layer on a top surface of the first plastic encapsulation layer, wherein the rewiring layer is electrically connected to the conductive pillars and the chip; attaching a connector to a top surface of the rewiring layer, wherein the connector is electrically connected to the rewiring layer; forming a second plastic encapsulation layer on the top surface of the rewiring layer, wherein the second plastic encapsulation layer encapsulates the connector; removing the substrate; and fabricating a solder bump under the first plastic encapsulation layer, wherein the solder bump is electrically connected to the conductive pillars.

### CROSS REFERENCE TO RELATED APPLICATION

The present application claims the benefit of priority to Chinese Patent Application No. CN 2019114073585, entitled “Wafer-Level SiP Module Structure and Method for Preparing the Same”, filed with CNIPA on Dec. 31, 2019, and Chinese Patent Application No. CN 2019224717993, entitled “Wafer-Level SiP Module Structure and Method for Preparing the Same”, filed with CNIPA on Dec. 31, 2019, the disclosure of which is incorporated herein by reference in its entirety.

### FIELD OF TECHNOLOGY

The present invention generally relates to semiconductor packaging, in particular, to a wafer-level SiP module structure and method for preparing the same.

### BACKGROUND

In the semiconductor industry, System-in-Package (SiP) modules integrate several functional chips into one package to achieve functional integration.

Existing SiP modules require complicated processes for conducting their front and back sides, and have a large package structure thickness and large size.

### SUMMARY

The present disclosure provides a method for preparing a wafer-level SiP module. The method includes: forming conductive pillars on a substrate; attaching a chip to the substrate; forming a first plastic encapsulation layer on the substrate, the first plastic encapsulation layer encapsulating the conductive pillars and the chip; forming a rewiring layer on a top surface of the first plastic encapsulation layer, wherein the rewiring layer is electrically connected to the conductive pillars and the chip; attaching a connector to a top surface of the rewiring layer, wherein the connector is electrically connected to the rewiring layer; forming a second plastic encapsulation layer on the top surface of the rewiring layer, wherein the second plastic encapsulation layer encapsulates the connector; removing the substrate; and fabricating a solder bump under the first plastic encapsulation layer, wherein the solder bump is electrically connected to the conductive pillars.

The present disclosure also provides a wafer-level SiP module, which includes: a first plastic encapsulation layer; one or more conductive pillar, formed in the first plastic encapsulation layer; a chip, placed in the first plastic encapsulation layer; a rewiring layer, formed on a top surface of the first plastic encapsulation layer, and electrically connected to the one or more conductive pillars and the chip; a second plastic encapsulation layer, formed on a top surface of the rewiring layer; a connector, formed on the top surface of the rewiring layer and in the second plastic encapsulation layer, wherein the connector is electrically connected to the rewiring layer; and a solder bump, formed on a bottom surface of the first plastic encapsulation layer and electrically connected to the one or more conductive pillars.

### BRIEF DESCRIPTION OF THE DRAWINGS

FIG. 1 shows a flowchart illustrating a method of preparing a wafer-level SiP module according to some embodiments of the present disclosure.

FIGS. 2˜18 show cross-sectional views of the intermediate structures after various steps in applying the method of preparing a wafer-level SiP module structure according to one embodiment; FIG. 18 is also a cross-sectional view of the final wafer-level SiP module structure according to the embodiment.

### DETAILED DESCRIPTION

One or more specific embodiments of the present disclosure will be described below. These described embodiments are only examples of the presently disclosed techniques, and are not intended to limit aspects of the presently disclosed invention. Additionally, in an effort to provide a concise description of these embodiments, all features of an actual implementation may not be described in the specification. It should be appreciated that in the development of any such actual implementation, numerous implementation-specific decisions must be made to achieve the developers' specific goals, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

The term regarding spatial relationships such as “lower,” “below,” “under,” and “on,” “above,” etc., are used for convenience of description to describe the relationship of one element or feature to another element or feature in a figure. It should be understood that in addition to the orientation shown in the figure, the spatial relationship terms are intended to include different orientations during use and operation. For example, if the device in the figures is rotated, then what is described as “below” or “beneath” or “under” may become “on” or “above” or “over.” Thus, the term “below” and “under” may include both upper and lower orientations. Device may additionally be oriented differently (e.g., rotated 90 degrees or other orientations), and the spatial relationship used in this description are interpreted accordingly. In addition, when a layer is referred to as being “between” two layers, it may be the only layer between the two layers, or one of a plurality of layers between the two layers. Further, the term “top”, “bottom”, “above”, “below”, “up”, or “down” may be relative to one surface of a horizontally-placed layer.

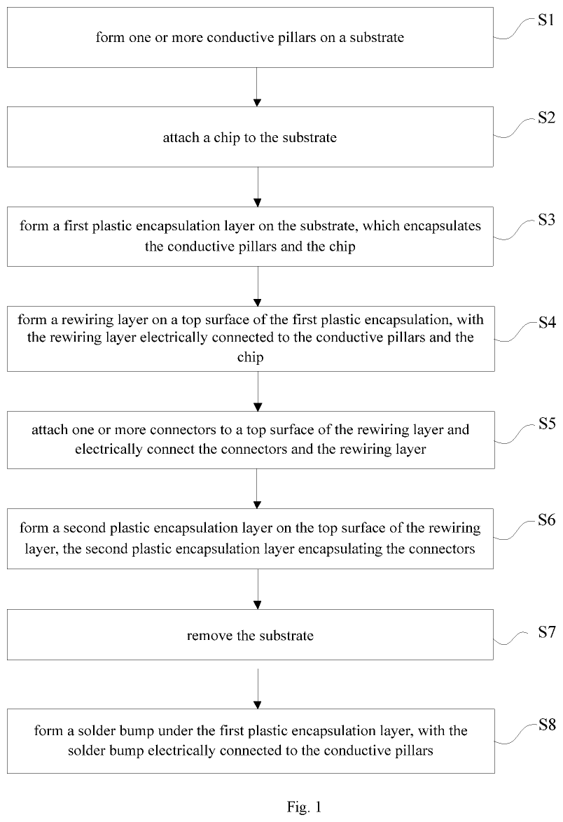

FIG. 1 shows a flowchart illustrating a method of preparing a wafer-level SiP module structure according to some embodiments of the present disclosure. The method of preparing a wafer-level SiP module structure includes steps: S1, forming one or more conductive pillars on a substrate; S2, attaching a chip to the substrate; S3, forming a first plastic encapsulation layer on the substrate, which encapsulates the conductive pillars and the chip; S4, forming a rewiring layer on a top surface of the first plastic encapsulation, with the rewiring layer electrically connected to the conductive pillars and the chip; S5, attaching one or more connectors to a top surface of the rewiring layer and electrically connecting the connectors and the rewiring layer; S6, forming a second plastic encapsulation layer on the top surface of the rewiring layer, the second plastic encapsulation layer encapsulating the connectors; S7, removing the substrate; and S8, forming a solder bump under the first plastic encapsulation layer, with the solder bump electrically connected to the conductive pillars.

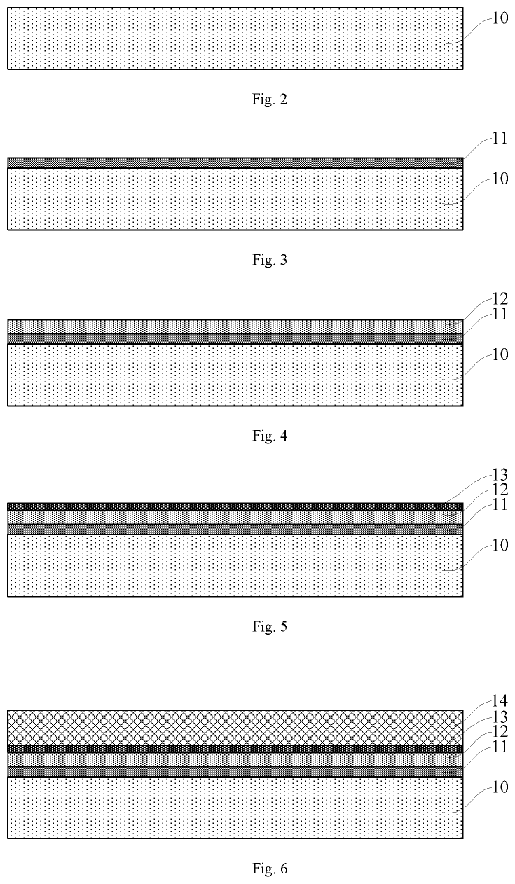

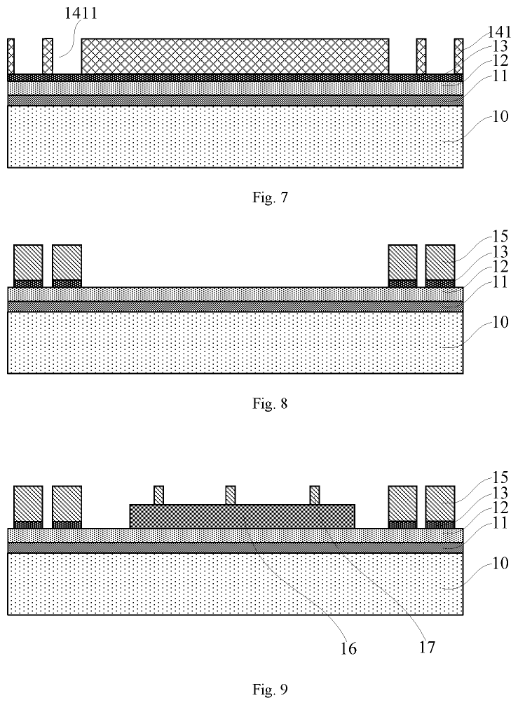

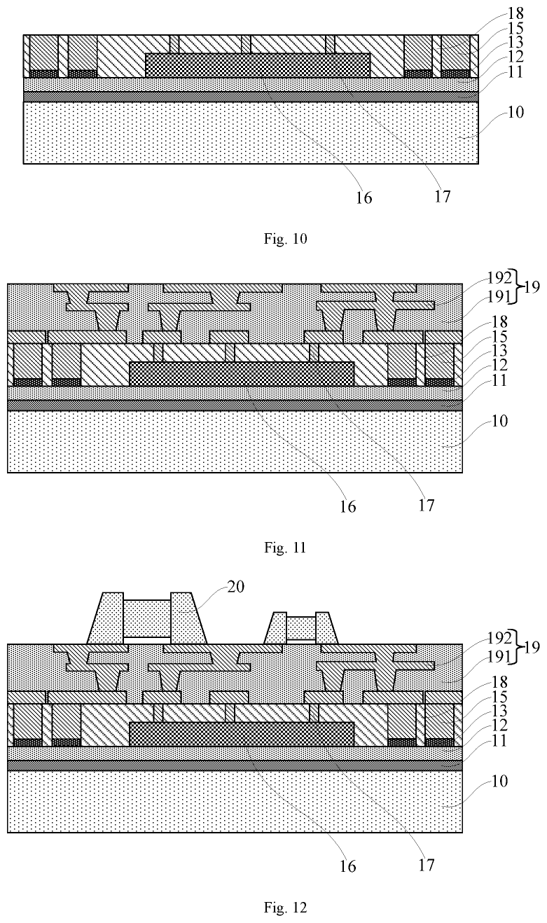

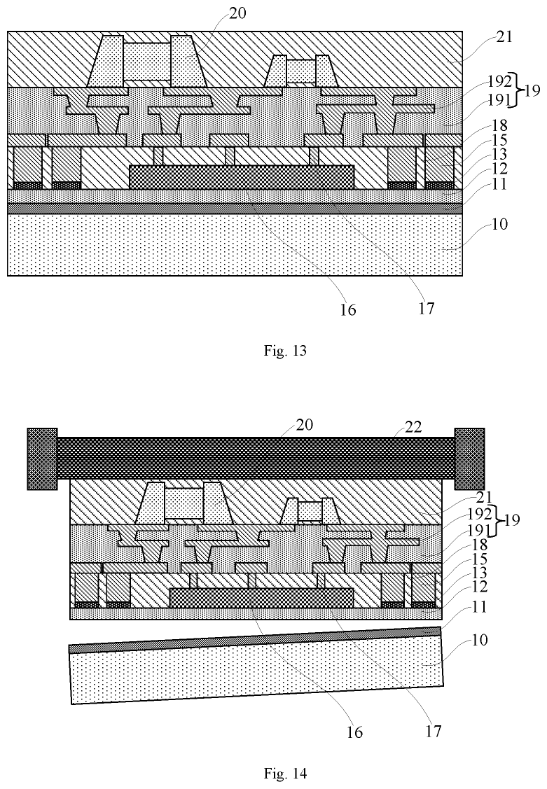

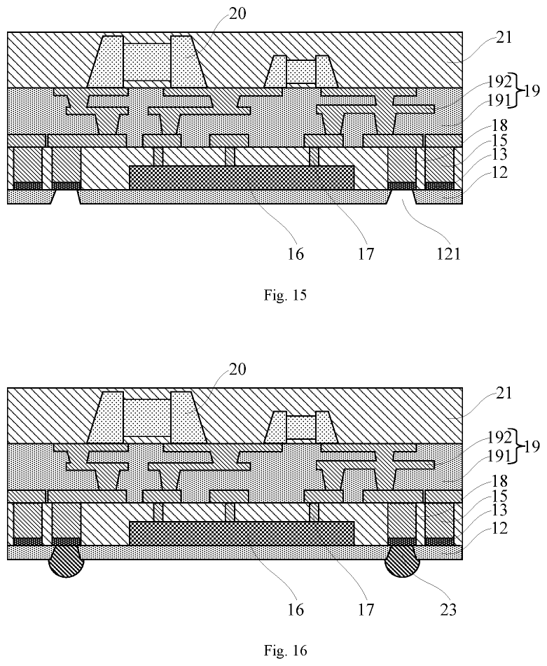

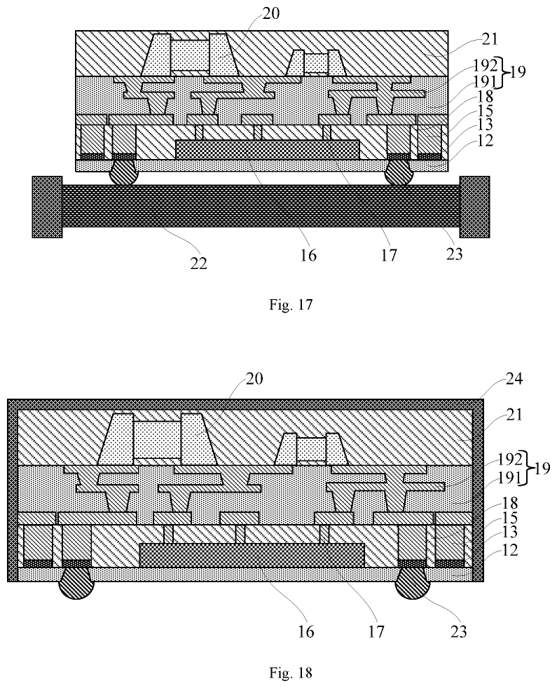

In some embodiments, the substrate 10 in FIG. 2 is made of one or more materials of silicon, glass, silicon oxide, ceramic, polymer, and metal. In some embodiments, the substrate 10 is round or square. In some embodiments, the substrate 10 includes a silicon wafer.

In some embodiments, as shown in FIGS. 3-5, the method of preparing a wafer-level SiP module structure further includes: forming a peeling layer 11 on a top surface of the substrate 10; forming a bottom dielectric layer 12 on a top surface of the peeling layer 11; and forming a metal seed layer 13 on a top surface of the bottom dielectric layer 12.

In some embodiments, the peeling layer 11 serves as a separation layer between the substrate 10 and the bottom dielectric layer 12. In some embodiments, the peeling layer 11 is made of adhesive materials with smooth surfaces. In some embodiments, there is a bonding force between the peeling layer 11 and the bottom dielectric layer 12, and there is a stronger bonding force between the peeling layer 11 and the substrate 10. Generally speaking, the bonding force between the peeling layer 11 and the substrate 10 is greater than the bonding force between the peeling layer 11 and dielectric layer 12.

In some embodiments, the peeling layer 11 includes a polymer layer or tape adhesive layer. More specifically, the peeling layer 11 can be made of a tape which has adhesives at both sides (for example, die attach film or non-conductive film), or adhesives made by a spin coating process. In some embodiments, the peeling layer 11 is a UV tape, which can be easily torn off after ultraviolet (UV) irradiation. In some embodiments, the peeling layer 11 can be made of one or more layers of materials prepared by physical vapor deposition or chemical vapor deposition, for example, epoxy, silicone rubber, polyimide (PI), polybenzoxazole (PBO), and benzocyclobutene (BCB). When the substrate 10 is subsequently removed, the peeling layer 11 can be removed by one of wet etching, chemical mechanical polishing and other methods.

In some embodiments, the peeling layer 11 can also be formed by an automatic placement process.

In some embodiments, the bottom dielectric layer 12 can be formed by a physical vapor deposition process or chemical vapor deposition process, and the bottom dielectric layer 12 can include a silicon oxide layer, a silicon nitride layer or a silicon oxynitride layer.

In some embodiments, the metal seed layer 13 can be formed by a sputtering process, and the metal seed layer 13 can be made of materials including, but not limited to, titanium, and copper. More specifically, the metal seed layer 13 can include a titanium layer and a copper layer, and the titanium layer is on the top surface of the bottom dielectric layer 12, the copper layer is on a top surface of the titanium layer.

In some embodiments, the conductive pillars 15 are formed on a top surface of the metal seed layer 13.

Referring to S1 in FIG. 1, and FIGS. 6-8, at S1, the conductive pillars 15 are formed on the substrate 10.

In some embodiments, S1 includes the following processes:

a mask layer 14 is formed on the top surface of the metal seed layer 13, as shown in FIG. 6; more specifically, in some embodiments, the mask layer 14 includes a photoresist layer, and a spin coating process is used to form the mask layer 14 on the top surface of the metal seed layer 13;

the mask layer 14 is patterned to obtain a patterned mask layer 141, with patterned openings 1411 formed in the patterned mask layer 141, and the patterned openings 1411 partially exposing the metal seed layer 13 and defining positions and shapes of the conductive pillars in the next step, as shown in FIG. 7; more specifically, the mask layer 14 can be patterned by photolithography;

the conductive pillars 15 are formed in the patterned openings 1411, as shown in FIG. 8; more specifically, in some embodiments, the conductive pillars 15 can be formed by a sputtering process; in some embodiments, the conductive pillars 15 includes metal conductive pillars, such as copper conductive pillars; and

the patterned mask layer 141 is then removed, and the part of the seed layer 13 that was previously covered by the patterned mask layer 141 and later exposed by the removal of the patterned mask layer is also removed, as shown in FIG. 8; more specifically, in some embodiments, the patterned mask layer 141 may be removed by an ashing process, and the part of the metal seed layer 13 that was previously covered by the patterned mask layer 141 may be removed by an etching process.

Referring to S2 in FIG. 1 and FIG. 9, at S2, the chip 16 is attached on the dielectric layer 12 over the substrate 10.

In some embodiments, the chip 16 is a functional chip.

In some embodiments, the chip 16 is attached on the dielectric layer over the substrate 10 facing upward. More specifically, the chip 16 is attached to the top surface of the dielectric layer 12 over the substrate 10 wherein the chip 16 faces upward.

In some embodiments, still referring to FIG. 9, after the chip 16 is attached to the substrate 10, a chip lead-out structure 17 is formed on a top surface of the chip 16.

In some embodiments, the chip lead-out structure 17 and the conductive pillars 15 are made of the same materials.

Referring to S3 in FIG. 1 and FIG. 10, at S3, a first plastic encapsulation layer 18 is formed on the substrate 10, and the first plastic encapsulation layer 18 encapsulates the conductive pillars 15 and the chip 16.

In some embodiments, the first plastic encapsulation layer 18 is formed by a molding under-fill process, an imprinting molding process, a transfer molding process, a liquid sealing plastic packaging process, a vacuum casting process, or a spin coating process. In some embodiments, the molding under-fill process is used to form the first plastic encapsulation layer 18, and the first plastic encapsulation layer 18 fills gaps between the conductive pillars 15 and the chip lead-out structure 17 smoothly and fast, which helps avoiding interface layering. It is worth mentioning that the molding under-fill process will not be as limited as the capillary under-fill process in the prior art, which greatly reduces the processing difficulty, can be used for smaller connection gaps, and is more suitable for stacked structures.

In some embodiments, the first plastic encapsulation layer 18 is made of one or more of materials including polymer-based materials, resin-based materials, polyimide, silicone, and epoxy.

In some embodiments, the first plastic encapsulation layer 18 encapsulates the chip 16, the conductive pillars 15, and the chip lead-out structure 17.

In some embodiments, initially, the top surface of the first plastic encapsulation layer 18 is higher than a top surface of the conductive pillars 15 and a top surface of the chip lead-out structure 17, and after the first plastic encapsulation layer 18 is formed, the first plastic encapsulation layer 18 is thinned down. More specifically, in some embodiments, the first plastic encapsulation layer 18 is thinned down by a chemical mechanical polishing process, so that the top surface of the first plastic encapsulation layer 18, the top surfaces of the conductive pillars 15, and the top surfaces of the chip lead-out structure 17 are flush at the same level, as shown in FIG. 10. In some cases, if initially the top surface of the first plastic encapsulation layer 18, the top surfaces of the conductive pillars 15, and the top surfaces of the chip lead-out structure 17 are already flush at the same level then the first plastic encapsulation layer 18 doesn't require planarization.

Referring to S4 in FIG. 1 and FIG. 11, at S4, the rewiring layer 19 is formed on the top surface of the first plastic encapsulation layer 18, and the rewiring layer 19 is electrically connected to the conductive pillars 15 and the chip 16.

In some embodiments, the rewiring layer 19 includes one or more interlayer dielectric layers 191 and one or more metal wiring layers 192. In some embodiments, as shown in FIG. 11, the rewiring layer 19 includes three metal wiring layers 192.

In some embodiments, the material of the interlayer dielectric layers 191 includes, but not limited to, a low-k dielectric material. The interlayer dielectric layers 191 may be made of one of epoxy, silica gel, PI, PBO, BCB, silicon oxide, phosphosilicate glass, and fluorine-containing glass, and the interlayer dielectric layers 191 can be formed by processes such as spin coating, chemical vapor deposition (CVD), and plasma enhanced CVD; the metal wiring layers 192 can be made of one or more of copper, aluminum, nickel, gold, silver, and titanium.

Referring to S5 in FIG. 1 and FIG. 12, at S5, connectors 20 are connected to the top surface of the rewiring layer 19, and electrically connected to the rewiring layer 19.

In some embodiments, S5 includes the following processes: mounting the connectors 20 on the top surface of the rewiring layer 19 based on solder paste and a reflow process using surface-mount technology; and cleaning the connectors 20 and the rewiring layer 19 after the mounting process to remove flux in the solder paste.

Referring to S6 in FIG. 1 and FIG. 13, at S6, the second plastic encapsulation layer 21 is formed on the top surface of the rewiring layer 19, and the second plastic encapsulation layer 21 encapsulates the connectors 20.

In some embodiments, the second plastic encapsulation layer 21 is formed by a molding under-fill process, an imprinting molding process, a transfer molding process, a liquid sealing plastic packaging process, a vacuum casting process, or a spin coating process. In some embodiments, the molding under-fill process is used to form the second plastic encapsulation layer 21, and the second plastic encapsulation layer 21 fills gaps between the connectors 20 smoothly and fast, which helps avoiding interface layering. It is worth mentioning that the molding under-fill process will not be as limited as the capillary under-fill process in the prior art, which greatly reduces the processing difficulty, can be used for smaller connection gaps, and is more suitable for stacked structures.

In some embodiments, the second plastic encapsulation layer 21 is made of one or more of polymer-based materials, resin-based materials, polyimide, silicone, and epoxy.

In some embodiments, initially, a top surface of the second plastic encapsulation layer 21 is higher than a top surface the connectors 20, and after the second plastic encapsulation layer 21 is formed, the second plastic encapsulation layer 21 is thinned. More specifically, in some embodiments, the second plastic encapsulation layer 21 is thinned by a chemical mechanical polishing process, so that the top surface of the second plastic encapsulation layer 21 and the top surface of the connectors 20 are flush, as shown in FIG. 13. In some embodiments, initially the top surface of the second plastic encapsulation layer 21, and the top surface of the connectors 20 are flush, as shown in FIG. 13, in which case, the second plastic encapsulation layer 21 doesn't need to be thinned.

Referring to S7 in FIG. 1 and FIG. 14, at S7, the substrate 10 is removed.

In some embodiments, the substrate 10 is removed by a grinding process, thinning process or tearing process. In some embodiments, the peeling layer 11 is peeled off to remove the substrate 10; more specifically, the intermediate structure obtained after S6 is attached to a blue film structure 22, with the top surface of the second plastic encapsulation layer 21 in contact with the blue film structure 22, and then the peeling layer 11 is peeled off to remove the substrate 10.

Referring to S8 in FIG. 1, the solder bump 23 is formed under the first plastic encapsulation layer 18, and electrically connected to the conductive pillars 15.

In some embodiments, S8 includes the following processes: an opening 121 is formed in the bottom dielectric layer 12, and the opening 121 partially exposes a bottom surface of the conductive pillars 15, as shown in FIG. 15; and the solder bump is formed by processes including but not limited to a sputtering process, as shown in FIG. 16.

In some embodiments, the solder bump 23 is made of one or more of copper and tin.

In some embodiments, after S8, the method of preparing a wafer-level SiP module structure further includes the following processes:

the intermediate structure obtained after S8 is cut to obtain several packaging structures, wherein each of the packaging structure includes the chip 16, the conductive pillars 15, the first plastic encapsulation layer 18, the rewiring layer 19, the second plastic encapsulation layer 21 and the connector 20; more specifically, the intermediate structure obtained after S8 is attached to the blue film structure 22 for cutting, and the solder bump 23 is in contact with the blue film structure 22, as shown in FIG. 17;

a shielding layer 24 is formed above and around the packaging structures, and the shielding layer 24 covers the top surface and sides of the second plastic encapsulation layer 21, sides of the rewiring layer 19, and sides of the first plastic encapsulation layer 18, as shown in FIG. 18.

In some embodiments, the shielding layer 24 is a metal shielding layer.

Referring to FIG. 18 in conjunction with FIGS. 2-17, the present disclosure also provides a wafer-level SiP module structure, which includes a first plastic encapsulation layer 18; conductive pillars 15, formed in the first plastic encapsulation layer 18; a chip 16, located in the first plastic encapsulation layer 18; a rewiring layer 19, formed on a top surface of the first plastic encapsulation layer 18 and electrically connected to the conductive pillars 15 and the chip 16; a second plastic encapsulation layer 21, formed on a top surface of the rewiring layer 19; a connector 20, formed on the top surface of the rewiring layer 19 and in the second plastic encapsulation layer 21, and electrically connected to the rewiring layer 19; and a solder bump 23, formed on a bottom surface of the first plastic encapsulation layer 18 and electrically connected to the conductive pillars 15.

In some embodiments, the wafer-level SiP module structure also includes: a seed layer 13, formed in the first plastic encapsulation layer 18 and on a bottom surface of the conductive pillars 15; a bottom dielectric layer 12, formed on a bottom surface of the first plastic encapsulation layer 18, and containing an opening 121 which partially exposes the seed layer 13. The solder bump 23 is formed in the opening 121, and electrically connected to the conductive pillars 15 through the seed layer 13.

In some embodiments, the seed layer 13 is made of titanium and copper. More specifically, the seed layer 13 may include a titanium layer and a copper layer, with the titanium layer formed on a top surface of the bottom dielectric layer 12, the copper layer formed on a top surface of the titanium layer. The bottom dielectric layer 12, in some embodiments, includes one or more of a silicon oxide layer, silicon nitride layer, and silicon oxynitride layer.

In some embodiments, the wafer-level SiP module structure also includes a chip lead-out structure 17, formed in the first plastic encapsulation layer 18 and on a top surface of the chip 16; the chip 16 is electrically connected to the rewiring layer 19 through the chip lead-out structure 17.

In some embodiments, the first plastic encapsulation layer 18 is made of one or more of polymer-based materials, resin-based materials, PI, silicone, and epoxy.

In some embodiments, the first plastic encapsulation layer 18 encapsulates the chip 16, the conductive pillars 15 and the chip lead-out structure 17.

In some embodiments, the conductive pillars 15 are metal conductive pillars, such as copper conductive pillar.

In some embodiments, the chip 16 is a functional chip.

In some embodiments, the chip 16 is attached to the substrate 10 facing up. More specifically, the chip 16 is attached to a top surface of the bottom dielectric layer 12 facing up.

In some embodiments, the rewiring layer 19 includes several interlayer dielectric layers 191 and one or more metal wiring layers 192. In some embodiments, as shown in FIG. 11, the rewiring layer 19 includes three metal wiring layers 192.

In some embodiments, the interlayer dielectric layers 191 are made of low-k dielectric materials. In some embodiments, the interlayer dielectric layers 191 are made of one of epoxy, silica gel, PI, PBO, BCB, silicon oxide, phosphosilicate glass, and fluorine-containing glass. In some embodiments, the interlayer dielectric layers 191 are formed by one or more of spin coating, CVD, plasma enhanced CVD, and other processes. The metal wiring layers 192 are made of one or more of copper, aluminum, nickel, gold, silver, and titanium.

In some embodiments, the second plastic encapsulation layer 21 is made of one or more of polymer-based materials, resin-based materials, polyimide, silicone, and epoxy.

In some embodiments, the solder bump 23 is made of one or more of copper and tin.

In some embodiments, the wafer-level SiP module structure also includes a shielding layer 24, which covers a top surface and sides of the second plastic encapsulation layer 21, the sides of the rewiring layer 19, and the sides of the first plastic encapsulation layer 18

In some embodiments, the shielding layer 24 is a metal shielding layer.

While particular elements, embodiments, and applications of the present invention have been shown and described, it is understood that the invention is not limited thereto because modifications may be made by those skilled in the art, particularly in light of the foregoing teaching. It is therefore contemplated by the appended claims to cover such modifications and incorporate those features which come within the spirit and scope of the invention.

### LIST OF REFERENCE NUMERALS

10 substrate
11 peeling layer
12 bottom dielectric layer
121 opening
13 seed layer
14 mask layer
141 patterned mask layer
1411 patterned openings
15 conductive pillars
16 chip
17 chip lead-out structure
18 first plastic encapsulation layer
19 rewiring layer
191 interlayer dielectric layers
192 metal wiring layers
20 connectors
21 second plastic encapsulation layer
22 blue film structure
23 solder bump
24 a shielding layer
S1˜S8 operations of a method of preparing a wafer-level SiP module structure

What is claimed is:

1. A method for preparing a wafer-level SiP module, comprising:
forming one or more conductive pillars on a substrate;
attaching a chip to the substrate;
forming a first plastic encapsulation layer on the substrate, wherein the first plastic encapsulation layer encapsulates the one or more conductive pillars and the chip;
forming a rewiring layer on a top surface of the first plastic encapsulation layer, wherein the rewiring layer is electrically connected to the one or more conductive pillars and the chip;
attaching a connector to a top surface of the rewiring layer, wherein the connector is electrically connected to the rewiring layer;
forming a second plastic encapsulation layer to encapsulate the connector and the top surface of the rewiring layer;
removing the substrate; and
fabricating a solder bump under the first plastic encapsulation layer, wherein the solder bump is electrically connected to the one or more conductive pillars.

2. The method for preparing the wafer-level SiP module according to claim 1, further comprising, before forming the one or more conductive pillars on the substrate:
forming a peeling layer on a top surface of the substrate;
forming a bottom dielectric layer on a top surface of the peeling layer; and
forming a seed layer on a top surface of the bottom dielectric layer, wherein the one or more conductive pillars are formed on a top surface of the seed layer.

3. The method for preparing the wafer-level SiP module according to claim 2, wherein the forming the one or more conductive pillars on the substrate comprises:
forming a mask layer on the top surface of the seed layer;
patterning the mask layer to form openings in the mask layer, wherein the openings partially expose the seed layer and define positions and shapes of the one or more conductive pillars;
forming the one or more conductive pillars by filling metal in the openings on the exposed seed layer; and
removing the mask layer and the seed layer which is outside the one or more conductive pillars.

4. The method for preparing the wafer-level SiP module according to claim 1, further comprising, before the attaching the chip to the substrate:
forming a chip lead-out structure on a top surface of the chip, wherein the chip is electrically connected to the rewiring layer through the chip lead-out structure, and wherein the first plastic encapsulation layer encapsulates the one or more conductive pillars, the chip, and the chip lead-out structure.

5. The method for preparing the wafer-level SiP module according to claim 1, wherein the attaching the connector to the top surface of the rewiring layer comprises:
mounting the connector on the top surface of the rewiring layer applying a surface-mount solder paste and flux reflow process; and
cleaning the connector and the rewiring layer after the mounting to remove flux from the solder paste.

6. The method for preparing the wafer-level SiP module according to claim 1, further comprising, after the fabricating a solder bump under the first plastic encapsulation layer:
applying a shielding layer on a top surface and sides of the wafer-level SiP module, wherein the shielding layer encloses a top surface and sides of the second plastic encapsulation layer, sides of the rewiring layer, and sides of the first plastic encapsulation layer.

7. A wafer-level SiP module, comprising:
a first plastic encapsulation layer;
one or more conductive pillar, formed in the first plastic encapsulation layer;
a chip, placed in the first plastic encapsulation layer;
a rewiring layer, formed on a top surface of the first plastic encapsulation layer, and electrically connected to the one or more conductive pillars and the chip;
a second plastic encapsulation layer, formed on a top surface of the rewiring layer;
a connector, formed on the top surface of the rewiring layer and encapsulated in the second plastic encapsulation layer, wherein the connector is electrically connected to the rewiring layer; and
a solder bump, formed on a bottom surface of the first plastic encapsulation layer and electrically connected to the one or more conductive pillars.

8. The wafer-level SiP module according to claim 7, further comprising:
a seed layer, formed in the first plastic encapsulation layer, wherein the one or more conductive pillars are formed on the seed layer; and
a bottom dielectric layer, formed on a bottom surface of the first plastic encapsulation layer, wherein an opening is formed in the bottom dielectric layer, and wherein the opening partially exposes the seed layer, wherein the solder bump is in the opening, and electrically connected to the one or more conductive pillars through the seed layer.

9. The wafer-level SiP module according to claim 7, further comprising:
a chip lead-out structure, formed on a top surface of the chip and disposed in the first plastic encapsulation layer, wherein the chip is electrically connected to the rewiring layer through the chip lead-out structure.

10. The wafer-level SiP module according to claim 7, further comprising:
a shielding layer, wherein the shielding layer forms an envelope outside a top surface and sides of the second plastic encapsulation layer, sides of the rewiring layer, and sides of the first plastic encapsulation layer.
